(19) United States
(12) Patent Application Publication
(10) Pub. No.: US 2018/0039596 A1
(43) Pub. Date: Feb. 8, 2018

(54) SUPPORTING INTERNAL RESISTIVE MEMORY FUNCTIONS USING A SERIAL PERIPHERAL INTERFACE (SPI)

(71) Applicant: QUALCOMM Incorporated, San Diego, CA (US)

(72) Inventor: Hyunsuk SHIN, San Diego, CA (US)

(21) Appl. No.: 15/228,975

(22) Filed: Aug. 4, 2016

(51) Int. Cl. G06F 13/42; G11C 14/00

(52) U.S. Cl. CPC G06F 13/4282; G11C 14/0045

(57) ABSTRACT

A method of serial peripheral interface (SPI) communications for a resistive memory. The method includes transmitting resistive memory commands via the SPI to operate the resistive memory according to an SPI protocol. The SPI protocol includes a command byte, an address byte, and data bytes.

### BACKGROUND

### Field

Certain aspects of the present disclosure generally relate to magnetic tunneling junction (MTJ) devices, and more particularly to an apparatus and method for supporting internal resistive memory functions using a serial peripheral interface (SPI).

### Background

Unlike conventional random access memory (RAM) chip technologies, in magnetic RAM (MRAM), data is stored by magnetization of storage elements. The basic structure of the storage elements consists of metallic ferromagnetic layers separated by a thin tunneling barrier. Typically, one of the ferromagnetic layers, for example the ferromagnetic layer underneath the barrier, has a magnetization that is fixed in a particular direction, and is commonly referred to as the pinned layer. The other ferromagnetic layers (e.g., the ferromagnetic layer above the tunneling barrier) have a magnetization direction that may be altered to represent either a “1” or a “0”, and are commonly referred to as the free layers. For example, a “1” may be represented when the free layer magnetization is anti-parallel to the fixed layer magnetization. In addition, a “0” may be represented when the free layer magnetization is parallel to the fixed layer magnetization or vice versa. One such device having a fixed layer, a tunneling layer, and a free layer is a magnetic tunnel junction (MTJ). The electrical resistance of an MTJ depends on whether the free layer magnetization and fixed layer magnetization are parallel or anti-parallel to each other. A memory device such as MRAM is built from an array of individually addressable MTJs.

To write data in a conventional MRAM, a write current, which exceeds a critical switching current, is applied through an MTJ. Application of a write current that exceeds the critical switching current changes the magnetization direction of the free layer. When the write current flows in a first direction, the MTJ may be placed into or remain in a first state in which its free layer magnetization direction and fixed layer magnetization direction are aligned in a parallel orientation. When the write current flows in a second direction, opposite to the first direction, the MTJ may be placed into or remain in a second state in which its free layer magnetization and fixed layer magnetization are in an anti-parallel orientation.

To read data in a conventional MRAM, a read current may flow through the MTJ via the same current path used to write data in the MTJ. If the magnetizations of the MTJ's free layer and fixed layer are oriented parallel to each other, the MTJ presents a parallel resistance. The parallel resistance is different than a resistance (anti-parallel) the MTJ would present if the magnetizations of the free layer and the fixed layer were in an anti-parallel orientation. In a conventional MRAM, two distinct states are defined by these two different resistances of an MTJ in a bitcell of the MRAM. The two different resistances indicate whether a logic “0” or a logic “1” value is stored by the MTJ.

Spin-transfer-torque magnetic random access memory (STT-MRAM) is an emerging nonvolatile memory that has advantages of non-volatility. In particular, STT-MRAM embedded with logic circuits may operate at a higher speed than off chip dynamic random access memory (DRAM). In addition, STT-MRAM has a smaller chip size than embedded static random access memory (eSRAM), virtually unlimited read/write endurance, as compared with FLASH, and a low array leakage current. In particular, STT-MRAM is fast, and non-volatile, relative to other non-volatile memory options, such as resistive RAM (RRAM), ferroelectric RAM (FRAM), eFlash, and the like.

STT efficiency and retention are specified parameters in the design of the MTJ for an embedded STT-MRAM. As a result, perpendicular STT-MRAM has become a leading candidate for providing next-generation embedded non-volatile memory. MRAM is a promising candidate for replacing NAND/NOR flash memory. Unfortunately, in spite of it many advantages, commercial MRAM adoption is quite limited.

### SUMMARY

A method of serial peripheral interface (SPI) communications for a resistive memory is described. The method may include transmitting resistive memory commands via the SPI to operate the resistive memory according to an SPI protocol. The SPI protocol may include a command byte, an address byte, and data bytes.

A serial peripheral interface (SPI) resistive memory system may include a resistive memory having a serial peripheral interface (SPI). The SPI resistive memory system may also include a memory controller coupled to the resistive memory. The memory controller may be operable to transmit resistive memory commands via the SPI according to an SPI protocol. The SPI protocol may include a command byte, an address byte, and data bytes.

A serial peripheral interface (SPI) resistive memory system may include a resistive memory having a serial peripheral interface (SPI). The (SPI) resistive memory system may also include a means for transmitting resistive memory commands to the resistive memory via the SPI according to an SPI protocol. The SPI protocol may include a command byte, an address byte, and data bytes.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a diagram of a magnetic tunnel junction (MTJ) device connected to an access transistor.

FIG. 2 is a conceptual diagram of a conventional magnetic random access memory (MRAM) cell including a magnetic tunnel junction (MTJ).

FIG. 3 is a cross-sectional diagram illustrating a conventional perpendicular magnetic tunnel junction (pMTJ) structure.

FIG. 4 is a system diagram of a serial peripheral interface-magnetic random access memory (SPI-MRAM) connected to a controller according to aspects of the present disclosure.

FIG. 5A is an operation diagram for a serial peripheral interface-magnetic random access memory (SPI-MRAM) cold power up operation protocol according to aspects of the present disclosure.

FIG. 5B is an operation diagram for a serial peripheral interface-magnetic random access memory (SPI-MRAM) warm power up operation protocol according to aspects of the present disclosure.

FIG. 5C is an operation diagram for a serial peripheral interface-magnetic random access memory (SPI-MRAM) built-in self-test (BIST) operation protocol according to aspects of the present disclosure.

FIG. 5D is an operation diagram for a serial peripheral interface-magnetic random access memory (SPI-MRAM) test register write operation protocol according to aspects of the present disclosure.

FIG. 5E is an operation diagram for a serial peripheral interface-magnetic random access memory (SPI-MRAM) direct access operation protocol according to aspects of the present disclosure.

FIG. 6 is a process flow diagram illustrating a method of implementing a serial peripheral interface-magnetic random access memory (SPI-MRAM) according to aspects of the present disclosure.

FIG. 7 is a block diagram showing an exemplary wireless communication system in which a configuration of the disclosure may be advantageously employed.

FIG. 8 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Spin-transfer torque magnetic random access memory (STT-MRAM) is an emerging nonvolatile memory that has advantages of non-volatility. In particular, STT-MRAM embedded with logic circuits may operate at a higher speed than off chip dynamic random access memory (DRAM). In addition, STT-MRAM has a smaller chip size than embedded static random access memory (eSRAM), virtually unlimited read/write endurance as compared with FLASH, and a low array leakage current. In particular, STT-MRAM is fast, and non-volatile, relative to other non-volatile memory options, such as resistive RAM (RRAM), ferroelectric RAM (FRAM), eFlash, and the like.

MRAM is a promising candidate for replacing NAND/NOR flash memory. Unfortunately, in spite of it many advantages, commercial MRAM adoption is limited. That is, an interface for supporting a commercial MRAM implementation is generally unavailable. Various aspects of the disclosure provide techniques for a serial peripheral interface (SPI) for magnetic random access memory (MRAM).

Aspects of the present disclosure are directed to a system including a resistive memory having a serial peripheral interface (SPI). The system also includes a memory controller operable to provide resistive memory commands via the SPI according to an SPI protocol. The SPI protocol may include command, address, and data bytes.

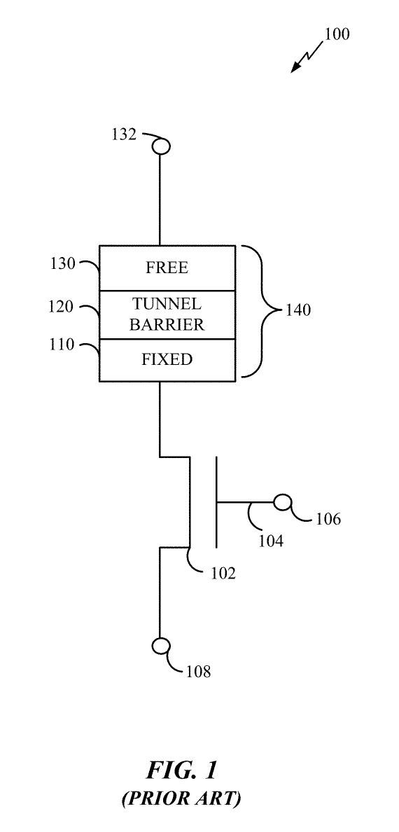

FIG. 1 illustrates a memory cell 100 of a memory device including a magnetic tunnel junction (MTJ) 140 coupled to an access transistor 102. The memory device may be a magnetic random access memory (MRAM) device that is built from an array of individually addressable MTJs. An MTJ stack may include a free layer, a fixed layer and a tunnel barrier layer, as well as one or more ferromagnetic (or anti-ferromagnetic) layers. Representatively, a free layer 130 of the MTJ 140 is coupled to a bit line 132. The access transistor 102 is coupled between a fixed layer 110 of the MTJ 140 and a fixed potential node 108. A tunnel barrier layer 120 is coupled between the fixed layer 110 and the free layer 130. The access transistor 102 includes a gate 104 coupled to a word line 106.

Synthetic anti-ferromagnetic materials may form the fixed layer 110 and the free layer 130. For example, the fixed layer 110 may include multiple material layers including a cobalt-iron-boron (CoFeB) layer, a ruthenium (Ru) layer and a cobalt-iron (CoFe) layer. In addition, the free layer 130 may also include multiple material layers including a cobalt-iron-boron (CoFeB) layer, a ruthenium (Ru) layer and a cobalt-iron (CoFe) layer. Further, the tunnel barrier layer 120 may be magnesium oxide (MgO).

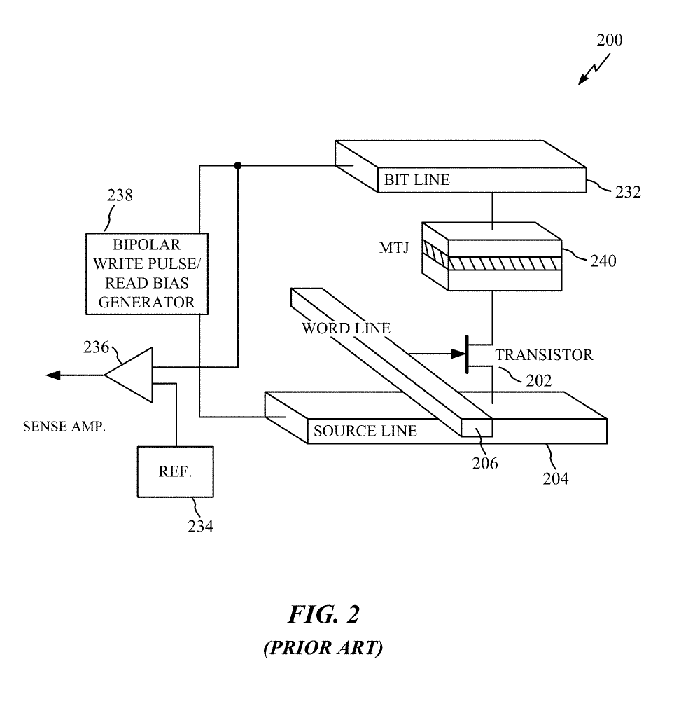

FIG. 2 illustrates a conventional STT-MRAM bit cell 200. The STT-MRAM bit cell 200 includes a magnetic tunnel junction (MTJ) storage element 240, a transistor 202, a bit line 232 and a word line 206. The MTJ storage element 240 is formed, for example, from at least two anti-ferromagnetic layers (a pinned layer and a free layer), each of which can hold a magnetic field or polarization, separated by a thin non-magnetic insulating layer (tunneling barrier). Electrons from the two ferromagnetic layers can penetrate through the tunneling barrier due to a tunneling effect under a bias voltage applied to the ferromagnetic layers. The magnetic polarization of the free layer can be reversed so that the polarity of the pinned layer and the free layer are either substantially aligned or opposite. The resistance of the electrical path through the MTJ varies depending on the alignment of the polarizations of the pinned and free layers. This variance in resistance may program and read the bit cell 200. The STT-MRAM bit cell 200 also includes a source line 204, a sense amplifier 236, read/write circuitry 238 and a bit line reference 234

Materials that form a magnetic tunnel junction (MTJ) of an MRAM generally exhibit high tunneling magneto resistance (TMR), high perpendicular magnetic anisotropy (PMA) and good data retention. MTJ structures may be made in a perpendicular orientation, referred to as perpendicular magnetic tunnel junction (pMTJ) devices. A stack of materials (e.g., cobalt-iron-boron (CoFeB) materials) with a dielectric barrier layer (e.g., magnesium oxide (MgO)) may be employed in a pMTJ structure. A pMTJ structure including a stack of materials (e.g., CoFeB/MgO/CoFeB) has been considered for MRAM structures.

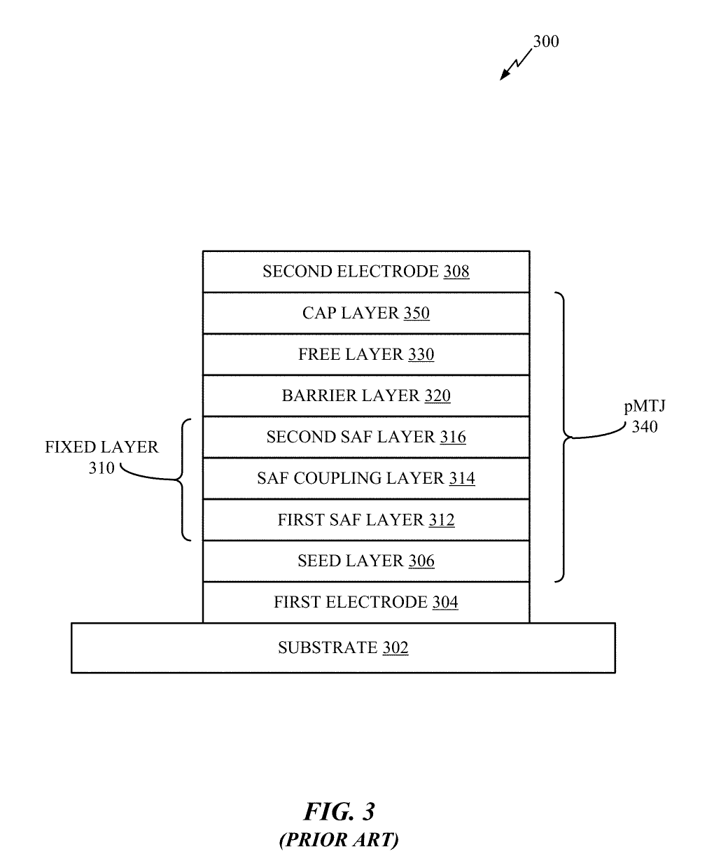

FIG. 3 illustrates a cross-sectional view of a conventional perpendicular magnetic tunnel junction (pMTJ) structure. Representatively, an MTJ structure 300, which is shown as a pMTJ structure 340 in FIG. 3, is formed on a substrate 302. The MTJ structure 300 may be formed on a semiconductor substrate, such as a silicon substrate, or any other alternative suitable substrate material. The MTJ structure 300 may include a first electrode 304, a seed layer 306, and a fixed layer 310. The fixed layer 310 includes a first synthetic antiferromagnetic (SAF) layer 312, a SAF coupling layer 314, and a second SAF layer 316. The MTJ structure 300 also includes a barrier layer 320, a free layer 330, a cap layer 350 (also known as a capping layer), and a second electrode 308. The MTJ structure 300 may be a part of various types of devices, such as a semiconductor memory device (e.g., MRAM).

In this configuration, the first electrode 304 and the second electrode 308 include conductive materials (e.g., tantalum (Ta)). In other configurations, the first electrode 304 and/or second electrode 308 may include other appropriate materials, including but not limited to platinum (Pt), copper (Cu), gold (Au), aluminum (Al), or other like conductive materials. The first electrode 304 and the second electrode 308 may employ different materials within the MTJ structure 300.

A seed layer 306 is formed on the first electrode 304. The seed layer 306 may provide a mechanical and crystalline substrate for the first SAF layer 312. The seed layer 306 may be a compound material, including but not limited to, nickel chromium (NiCr), nickel iron (NiFe), NiFeCr, or other suitable materials for the seed layer 306. When the seed layer 306 is grown or otherwise coupled to the first electrode 304, a smooth and dense crystalline structure results in the seed layer 306. In this configuration, the seed layer 306 promotes growth of subsequently formed layers in the MTJ structure 300 according to a specific crystalline orientation. The crystalline structure of the seed layer 306 may be selected to be any crystal orientation within the Miller index notation system, but is often chosen to be in the (111) crystal orientation.

A first SAF layer 312 is formed on the seed layer 306. The first SAF layer 312 includes a multilayer stack of materials formed on the seed layer 306, which may be referred to herein as a first anti-parallel pinned layer (AP1). The multilayer stack of materials in the first SAF layer 312 may be an anti-ferromagnetic material or a combination of materials to create an anti-ferromagnetic moment in the first SAF layer 312. The multilayer stack of materials forming the first SAF layer 312 include, but are not limited to, cobalt (Co), cobalt in combination with other materials such as nickel (Ni), platinum (Pt), or palladium (Pd), or other like ferromagnetic materials.

An SAF coupling layer 314 is formed on the first SAF layer 312, and promotes magnetic coupling between the first SAF layer 312 and a second SAF layer 316. The second SAF layer 316 has a magnetic orientation anti-parallel with the first SAF layer 312. The SAF coupling layer 314 includes material that aides in this coupling including, but not limited to, ruthenium (Ru), tantalum (Ta), gadolinium (Gd), platinum (Pt), hafnium (Hf), osmium (Os), rhodium (Rh), niobium (Nb), terbium (Tb), or other like materials. The SAF coupling layer 314 may also include materials to provide mechanical and/or crystalline structural support for the first SAF layer 312 and the second SAF layer 316.

The second SAF layer 316 is formed on the SAF coupling layer 314. The second SAF layer 316 may have similar materials as the first SAF layer 312, but may include other materials. The combination of the first SAF layer 312, the SAF coupling layer 313, and the second SAF layer 316 forms the fixed layer 310 including the SAF reference layers, which is often referred to as a “pinned layer” in the MTJ structure 300. The fixed layer 310 fixes, or pins, the magnetization direction of the SAF reference layers (e.g., 312, 314, 316) through anti-ferromagnetic coupling. As described herein, the second SAF layer 316 may be referred to as a second anti-parallel pinned layer (AP2). In this arrangement, the first SAF layer 312 may be referred to as a first anti-parallel pinned layer (AP1) that is separated from the second anti-parallel pinned layer (AP2) by the SAF coupling layer 314 to form the fixed layer 310. The fixed layer 310 may include a cobalt-iron-boron (CoFeB) film. The fixed layer 310 may also include other ferromagnetic material layers, such as CoFeTa, NiFe, Co, CoFe, CoPt, CoPd, FePt, or any alloy of Ni, Co and Fe.

A TMR enhancement layer of the fixed layer 310 abutting the barrier layer 320 may be formed of a material, such as CoFeB, that provides a crystalline orientation for the barrier layer 320. As with the seed layer 306, the material in the fixed layer 310 provides a template for subsequent layers to be grown in a specific crystalline orientation. This orientation may be in any direction within the Miller index system, but is often in the (100) (or (001)) crystal orientation.

The barrier layer 320 (also referred to as a tunnel barrier layer) is formed on the fixed layer 310. The barrier layer 320 provides a tunnel barrier for electrons travelling between the fixed layer 310 and the free layer 330. The barrier layer 320, which may include magnesium oxide (MgO), is formed on the fixed layer 310 and may have a crystalline structure. The crystalline structure of the barrier layer 320 may be in the (100) direction. The barrier layer 320 may include other elements or other materials, such as aluminum oxide (A10), aluminum nitride (AlN), aluminum oxynitride (AlON), or other non-magnetic or dielectric material. The thickness of the barrier layer 320 is selected so that electrons can tunnel from the fixed layer 310 through the barrier layer 320 to the free layer 330 when a biasing voltage is applied to the MTJ structure 300.

The free layer 330, which may be cobalt-iron-boron (CoFeB), is formed on the barrier layer 320. The free layer 330, when initially deposited on the barrier layer 320, is an amorphous structure. That is, the free layer 330 does not have a crystalline structure when initially deposited on the barrier layer 320. The free layer 330 is also an anti-ferromagnetic layer or multilayer material, which may include similar anti-ferromagnetic materials as the fixed layer 310 or may include different materials.

In this configuration, the free layer 330 includes an anti-ferromagnetic material that is not fixed or pinned in a specific magnetic orientation. The magnetization orientation of the free layer 330 is able to rotate to be in a parallel or an anti-parallel direction to the pinned magnetization of the fixed layer 310. A tunneling current flows perpendicularly through the barrier layer 320 depending upon the relative magnetization directions of the fixed layer 310 and the free layer 330.

A cap layer 350 is formed on the free layer 330. The cap layer 350 may be a dielectric layer, or other insulating layer, to allow containment of the magnetic and electric fields between the free layer 330 and the fixed layer 310. The cap layer 350 helps reduce the switching current density that switches the MTJ structure 300 from one orientation (e.g., parallel) to the other (e.g., anti-parallel). The cap layer 350, which may also be referred to as a capping layer, may be an oxide, such as, for example, amorphous aluminum oxide (AlOx) or amorphous hafnium oxide (HfOx). The cap layer 350 may also be other materials, such as magnesium oxide (MgO) or other dielectric materials without departing from the scope of the present disclosure.

The second electrode 308 is formed on the cap layer 350. In one configuration, the second electrode 308 includes tantalum. Alternatively, the second electrode 308 includes any other suitable conductive material for electrical connection of the MTJ structure 300 to other devices or portions of a circuit. Formation of the second electrode 308 on the cap layer 350 completes the MTJ structure 300.

### Serial Peripheral Interface-Magnetic Random Access Memory (SPI-MRAM)

Spin-transfer-torque magnetic random access memory (STT-MRAM) is an emerging nonvolatile memory that has advantages of non-volatility. In particular, STT-MRAM embedded with logic circuits may operate at a higher speed than off chip dynamic random access memory (DRAM). In addition, STT-MRAM has a smaller chip size than embedded static random access memory (eSRAM), virtually unlimited read/write endurance, as compared with FLASH, and a low array leakage current. In particular, STT-MRAM is fast, and non-volatile, relative to other non-volatile memory options, such as resistive RAM (RRAM), ferroelectric RAM (FRAM), eFlash, and the like.

STT efficiency and retention are specified parameters in the design of the MTJ for an embedded STT-MRAM. As a result, perpendicular STT-MRAM has become a leading candidate for providing next-generation embedded non-volatile memory. MRAM is a promising candidate for replacing NAND/NOR flash memory. Unfortunately, in spite of it many advantages, commercial MRAM adoption is limited. That is, an interface for supporting a commercial MRAM implementation is generally unavailable. Therefore, adoption of MRAM technology may be improved by adapting the existing serial peripheral interface-NOR (SPI-NOR) protocols with an SPI-MRAM interface for operating, debugging, and monitoring MRAM.

Current SPI-NOR uses SPI technology for facilitating communication between a processor and a peripheral device, such as NOR flash memory. For example, a standard SPI-NOR includes both hardware (e.g., signal pins) and software (e.g., command sets) for communicating with a processor as well as other peripheral components. As such, a standard SPI-NOR protocol architecture may be used to provide a framework in which SPI-MRAM may be easily and inexpensively integrated to promote commercial MRAM adoption.

Aspects of the present disclosure are directed to a system including a resistive memory having a serial peripheral interface (SPI). The system also includes a memory controller operable to provide resistive memory commands via the SPI according to an SPI protocol. The SPI protocol may include command, address, and data bytes.

Another aspect of the present disclosure includes a method of providing resistive memory commands via a serial peripheral interface (SPI) according to an SPI protocol. The SPI protocol may include command, address, and data bytes. The method may also include sending a command byte specific to resistive memory commands. The method may further include embedding resistive memory functions in an address byte of the SPI protocol. The method may also include remapping signal pin definitions of the SPI interface. In addition, the method may include sending dummy data bytes to deliver a clock toggling signal to specify toggling of a clock signal.

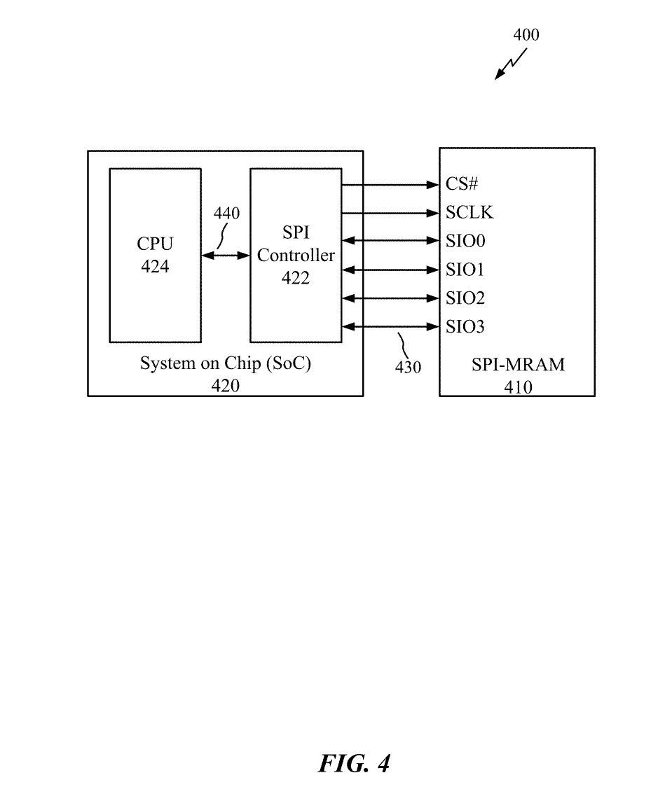

FIG. 4 is a system diagram 400 of a serial peripheral interface-magnetic random access memory (SPI-MRAM) 410 connected to a resistive memory controller 422 according to aspects of the present disclosure. The SPI-MRAM 410 provides a low cost high density non-volatile memory storage solution for embedded systems based on current SPI-NOR protocols. The SPI-MRAM 410 achieves this by using SPI communications protocols to enable communication between an MRAM chip located on the SPI-MRAM 410 and a processor, such as a CPU 424. By leveraging current existing SPI protocols based in hardware, the SPI-MRAM 410 may be easily integrated into current computing systems for wider industry MRAM adoption.

For example, the SPI-MRAM 410 (e.g., an 8-pin/ball small outline package (SOP)/ball grid array (BGA)) may include 8 pins/balls. Each of the pins/balls of the SPI-MRAM 410 may correspond to standard SPI signal pins for: chip select, active low CS#; serial data output/serial data input output 1 SO/SIO1; write protect, active low/serial data input output 2 WP#SIO2; ground VSS; power supply VCC; reset, active low/serial data input output 3 Reset#SIO3; serial clock SCLK; and serial data input/serial data input output 0 SI/SIO0. These signal pins enable communication between processors (e.g., CPU 424) and peripheral components (e.g., SPI-MRAM 410).

In an aspect, the SPI-MRAM 410 is coupled to processing components using a standard serial peripheral interface (SPI) 430 (e.g., an SPI bus). For example, a resistive memory controller 422 (e.g., an SPI controller) is operably coupled to the SPI-MRAM 410 via the SPI 430. The resistive memory controller 422 provides MRAM commands (e.g., resistive memory commands) according to standard SPI protocols. For example, the SPI protocol (e.g., command sets) may include command, address, and data bytes.

The resistive memory controller 422 may further be coupled via a communicative coupling 440 (e.g., a bus) to a processor (e.g., a central processing unit (CPU)) 424 for sending and receiving instructions. In one aspect of the disclosure, the CPU 424 and the resistive memory controller 422 are implemented as a system on chip (SoC) 420.

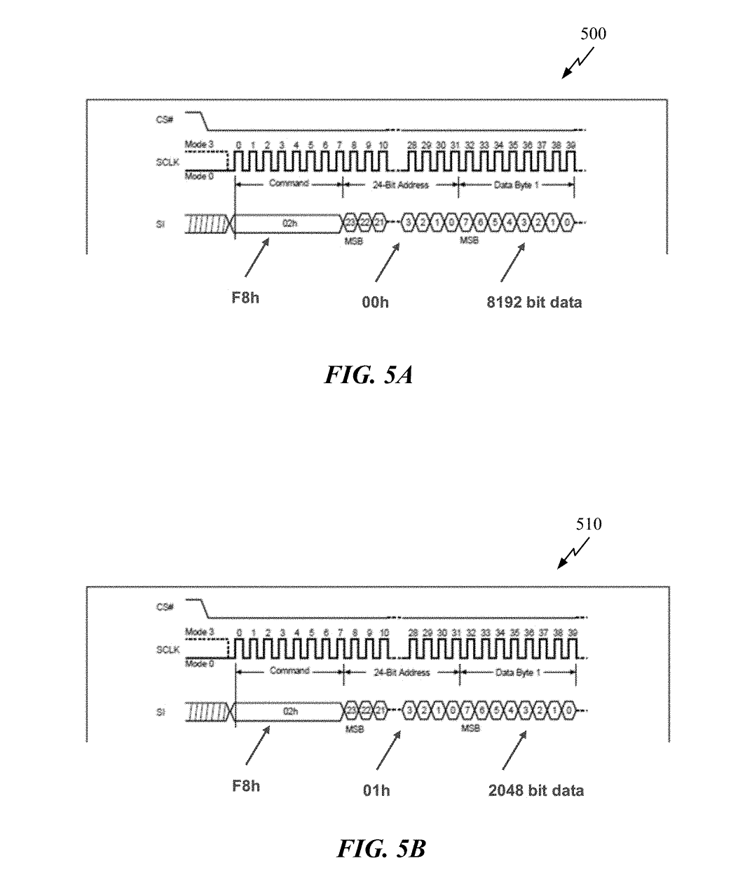

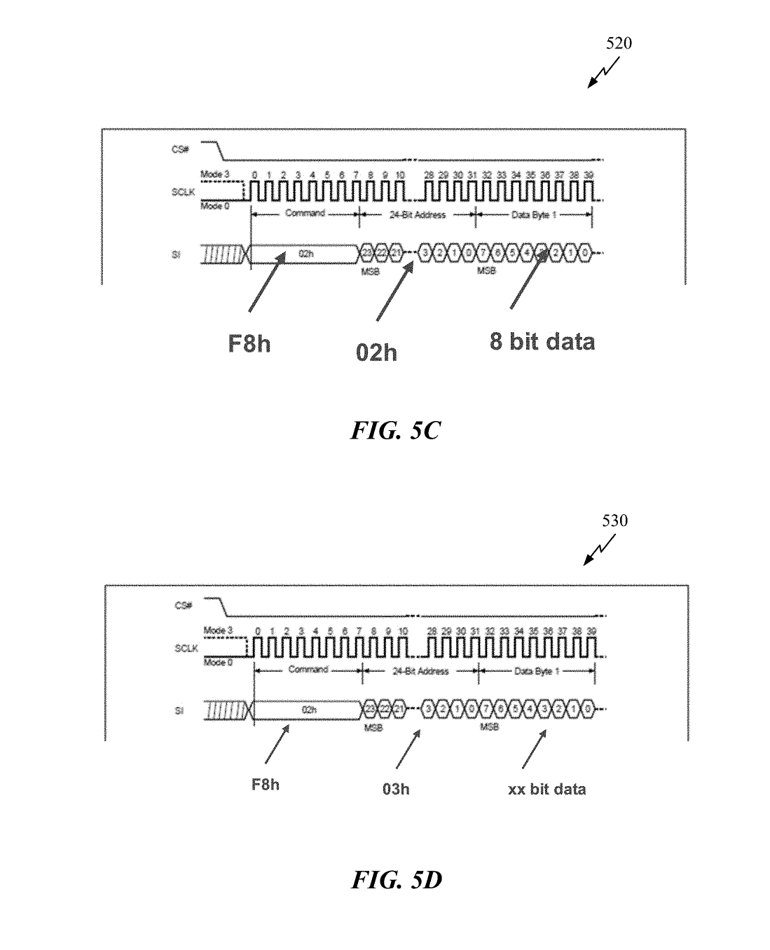

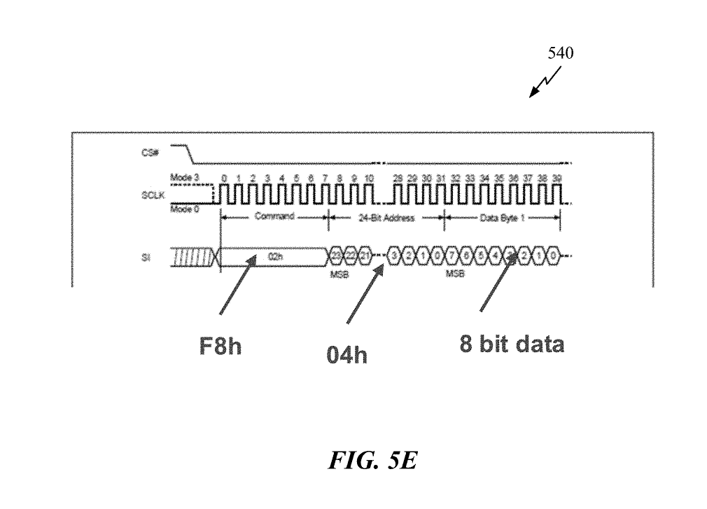

FIGS. 5A-5E illustrate operation diagrams for a serial peripheral interface-magnetic random access memory (SPI-MRAM) that leverages standard serial peripheral interface-NOR (SPI-NOR) protocols according to aspects of the present disclosure. The SPI-MRAM may be supported by the resistive memory controller 422 (FIG. 4) for implementing the SPI-MRAM protocol. For example, an 8-pin/ball small outline package (SOP) may include 8 pins/balls, which may be assigned to SPI-MRAM functions based on standard SPI-NOR protocols, as described above in relation to FIG. 4. The 8-pin/ball SOP may be coupled to a resistive memory device (e.g., an MRAM device) for providing clock toggling for internal MRAM operations, remapping signal pins, and writing test registers. As described, the SPI-MRAM uses the hardware and software infrastructure established by SPI-NOR protocols for inexpensive and efficient implementation.

According to an aspect, SPI-MRAM command signals may be based on standard SPI-NOR protocols. For example, a standard SPI-NOR protocol in operation uses the chip select CS#, serial clock SCLK, and serial data input SI signals for communicating command sets. The chip select CS# signal is low while the serial clock SCLK signal alternates between a high (e.g., mode 3) and a low (e.g., mode 0) state. A command signal (e.g., 02h) may be sent through the serial data input SI signal during eight serial clock SCLK cycles, a 24-bit address signal may be sent through the serial data input SI signal during 24 serial clock SCLK cycles, and any number of data bits (e.g., one or more bits) may be sent through the serial data input SI signal during a corresponding number of serial clock SCLK cycles (e.g., one or more cycles).

Similarly, the SPI-NOR command signals identified above may be adapted for enabling SPI-MRAM internal operations, debugging, and monitoring. For example, an SPI-MRAM specific command signal (e.g., F8h) indicates an operation to be performed. An address signal that follows indicates a particular MRAM function to be initiated. Finally, a data signal that may be of various lengths depending on the particular MRAM function may either initiate a desired clock toggling length (e.g., as dummy bytes), or be written into an internal test register. Other than the command signal, the rest of the signals can be based on standard SPI-NOR command sets.

A distinction between the SPI-NOR and SPI-MRAM command sets is that the address signals of SPI-NOR are used as the command type for SPI-MRAM. For example, SPI-NOR command signals use hexadecimal values, such as ooh, 01h, 02h, 03h, 04h, etc., as address signals for the SPI-MRAM. Additionally, the SPI-MRAM uses a command signal (e.g., F8h) that is not defined for SPI-NOR. The command signal (e.g., F8h) may be programmed using software so that it is recognized by the SPI-MRAM, without using new hardware.

Advantages of adapting hardware aspects of standard SPI protocols for MRAM include usage of the serial clock SCLK signal as a local clock. By using the serial clock SCLK signal as provided by the signal pin, power usage is reduced and space is saved on the MRAM from having to include an internal clock (e.g., a dedicated crystal oscillator, self-generating clock circuitry, etc.). Because the serial clock SCLK signal only toggles when there is an external data access request, dummy bytes may be used to deliver clock toggling without relying on receiving an external data access request. Additionally, as seen above, the SPI-MRAM communicates using a similar command set as SPI-NOR, so there is minimal re-programming of commands.

FIG. 5A is an operation diagram for an SPI-MRAM cold power up operation protocol according to aspects of the present disclosure. A cold power up operation 500 may include reference cell writing, initialization, and the like. According to an aspect, a resistive memory controller (e.g., SPI controller) issues a special operation with an 8-bit command signal, F8h, a 24-bit address signal, ooh, and a data signal of 8192 bits. In this case, the 00h address signal indicates the cold power up operation 500 is to be performed, and the data signal may be of various lengths depending on a desired clock toggling length.

In operation, the SPI-MRAM protocol uses the chip select CS#, serial clock SCLK, and serial data input SI signals for communicating command sets in regards to the cold power up operation 500. While the chip select CS# signal is low, the serial clock SCLK signal alternates between a high (e.g., mode 3) and a low (e.g., mode 0) state for toggling the cold power up operation 500. The 8-bit command signal (e.g., F8h) is sent through the serial data input SI signal during eight serial clock SCLK cycles. The 24-bit address signal (e.g., 00h) is sent through the serial data input SI signal during 24 serial clock SCLK cycles. Transfer of the command signal, address bit, and data bits may each begin on a rising edge of the serial clock SCLK signal. Because the serial clock SCLK signal only toggles when there is an external data access request, dummy bytes (e.g., the data signal) are used to deliver clock toggling without relying on receiving an external data access request. For example, in this case, 8192 bits may be sent through the serial data input SI signal to toggle a corresponding number of serial clock SCLK cycles (e.g., 8192 cycles).

FIG. 5B is an operation diagram for an SPI-MRAM warm power up operation protocol according to aspects of the present disclosure. A warm power up operation 510 may include sense amplifier offset cancellation, data scrubbing, and the like. For this case, a resistive memory controller (e.g., a SPI controller) issues a special operation with an 8-bit command signal, F8h, a 24-bit address signal, 01h, and a 2048 bit data signal. The address signal, 01h, indicates the warm power up operation 510 is to be performed.

Similar to the above, the SPI-MRAM protocol uses the chip select CS#, serial clock SCLK, and serial data input SI signals for communicating command sets in regards to the warm power up operation 510. While the chip select CS# signal is low, the serial clock SCLK signal alternates between a high (e.g., mode 3) and a low (e.g., mode 0) state. The command signal for F8h is sent through the serial data input SI signal during eight serial clock SCLK cycles. The 24-bit address signal for 01h is sent through the serial data input SI signal during 24 serial clock SCLK cycles. Transfer of the command signal, address bit, and data bits may each begin on a rising edge of the serial clock SCLK signal.

Because the serial clock SCLK signal only toggles when there is an external data access request, dummy bytes (e.g., the data signal) may be used to deliver clock toggling without relying on receiving an external data access request. For example, in this case, 2048 bits may be sent through the serial data input SI signal to toggle a corresponding number of serial clock SCLK cycles (e.g., 2048 cycles). Because the warm power up operation 510 requires less time to complete than the cold power up operation 500, fewer data bits are used to toggle the serial clock SCLK signal.

FIG. 5C is an operation diagram for an SPI-MRAM built-in self-test (BIST) operation protocol according to aspects of the present disclosure. A BIST operation 520 may be performed during manufacturing of the MRAM to check the integrity of MRAM cells. The BIST operation 520 may be triggered by joint test action group (JTAG) commands that involve JTAG defined pins.

For example, the resistive memory controller 422 issues a special operation with a command signal of F8h (e.g., 8 bits), an address signal of 02h (e.g., 24 bits), and a data signal of 8 bits. The data signal is ignored by the SPI-MRAM, and is used for clock toggling for the internal operation. Here, the address signal 02h indicates that the BIST operation 520 is being performed. In this aspect of the present disclosure, an SPI-MRAM may include remapped signal pins.

Accordingly, the SPI pins are remapped to JTAG pins for the BIST operation 520. For example, the chip select CS# signal pin is remapped to BIST_TCK (e.g., input), the serial data input output 0 SIO0 signal pin is remapped to BIST_TRST_N (e.g., input), the serial data input output 1 SIO1 signal pin is remapped to BIST_TMS (e.g., input), the serial data input output 2 SIO2 signal pin is remapped to BIST_TDI (e.g., input), and the serial data input output 3 SIO3 signal pin is remapped to BIST_TDO (e.g., output).

The SPI-MRAM protocol operates similar to the above cases. The chip select CS#, serial clock SCLK, and serial data input SI signals are used to communicate command sets. The chip select CS# signal is low, and the serial clock SCLK signal alternates between a high (e.g., mode 3) and a low (e.g., mode 0) state. The command signal (e.g., F8h) is sent through the serial data input SI signal during eight serial clock SCLK cycles. A 24-bit address signal (e.g., 02h) is sent through the serial data input SI signal during 24 serial clock SCLK cycles. Any number of data bits (e.g., 8) may be sent through the serial data input SI signal during a corresponding number of serial clock SCLK cycles (e.g., 8). Transfer of the command signal, address bit, and data bits correspond to a rising edge of the serial clock SCLK signal.

FIG. 5D is an operation diagram for an SPI-MRAM test register write operation protocol according to aspects of the present disclosure. A test register write operation 530 may include several test registers for configuring MRAM internal behavior and characteristics. A resistive memory controller (e.g., a SPI controller) issues a special operation with a command signal of F8h (e.g., 8 bits), an address signal of 03h (e.g., 24 bits), and a data signal of X bits, where X is a number of bits to be written into the test register. In this case, the address signal 03h indicates the test register write operation 530 is to be performed. The data signal may be of various lengths depending on the desired number of bits to be written into the test register.

In operation, the SPI-MRAM protocol uses the chip select CS#, serial clock SCLK, and serial data input SI signals for communicating command sets. The chip select CS# signal is low while the serial clock SCLK signal alternates between a high (e.g., mode 3) and a low (e.g., mode 0) state. The command signal (e.g., F8h) is sent via the serial data input SI signal during eight serial clock SCLK cycles. A 24-bit address signal (e.g., 03h) is sent via the serial data input SI signal during 24 serial clock SCLK cycles. The data signal both drives the serial clock SCLK signal and is also written into the test register. For example, any number of data bits (e.g., one or more bits) may be sent via the serial data input SI signal during a corresponding number of serial clock SCLK cycles (e.g., one or more cycles). As before, the command signal, address bits, and data bits are transferred on a rising edge of the serial clock SCLK signal.

FIG. 5E is an operation diagram for an SPI-MRAM direct access operation protocol according to aspects of the present disclosure. A direct access operation 540 may include testing, debugging, and direct access to an MRAM cell without using the SPI interface. A host controller, such as the resistive memory controller 422, issues a special operation with a command signal of F8h (e.g., 8 bits), an address signal of 04h (e.g., 24 bits), and a data signal of 8 bits. In this case, 04h indicates the direct access operation 540 is to be performed. Additionally, the data signal is ignored by the SPI-MRAM, and is used for clock toggling for the internal operation.

According to an aspect, the SPI pins are remapped to MRAM direct access pins for the direct access operation 540. For example, the chip select CS# signal pin is remapped to MRAM_CS (e.g., input), the serial data input output 0 SIO0 signal pin is remapped to MRAM_WE (e.g., input), the serial data input output 1 SIO1 signal pin is remapped to MRAM_ADDR[0] (e.g., input), the serial data input output 2 SIO2 signal pin is remapped to MRAM_DIN[0] (e.g., input), and the serial data input output 3 SIO3 signal pin is remapped to MRAM_DOUT[0] (e.g., output).

Similar to the above cases, the SPI-MRAM protocol uses the chip select CS#, serial clock SCLK, and serial data input SI signals for communicating command sets. While the chip select CS# signal is low, the serial clock SCLK signal alternates between a high (e.g., mode 3) and a low (e.g., mode 0) state. The command signal (e.g., F8h) is sent through the serial data input SI signal during eight serial clock SCLK cycles. A 24-bit address signal (e.g., 04h) is sent through the serial data input SI signal during 24 serial clock SCLK cycles. Any number of data bits (e.g., 8) may be sent through the serial data input SI signal during a corresponding number of serial clock SCLK cycles (e.g., 8). Transfer of the command signal may begin on a rising edge of the serial clock SCLK signal. Transfer of each address bit and data bit may also begin on a rising edge of the serial clock SCLK signal.

In related versions, a command byte occurs during a command cycle of the serial clock SCLK signal, an address byte occurs during an address cycle of the serial clock SCLK signal, and data bytes occur during data cycles of the serial clock SCLK signal. The command byte may be 8 bits, the address byte may be 24 bits, and the data bytes may be one or more bits. The number of bits of each of the command byte, address byte, and data bytes may correspond to a number of pulses in the serial clock SCLK signal. These bit values are exemplary only, and other values may be used. Because the serial clock SCLK signal only toggles when there is an external data access request, dummy bytes (e.g., the data bytes) may be used to deliver clock toggling without relying on receiving an external data access request.

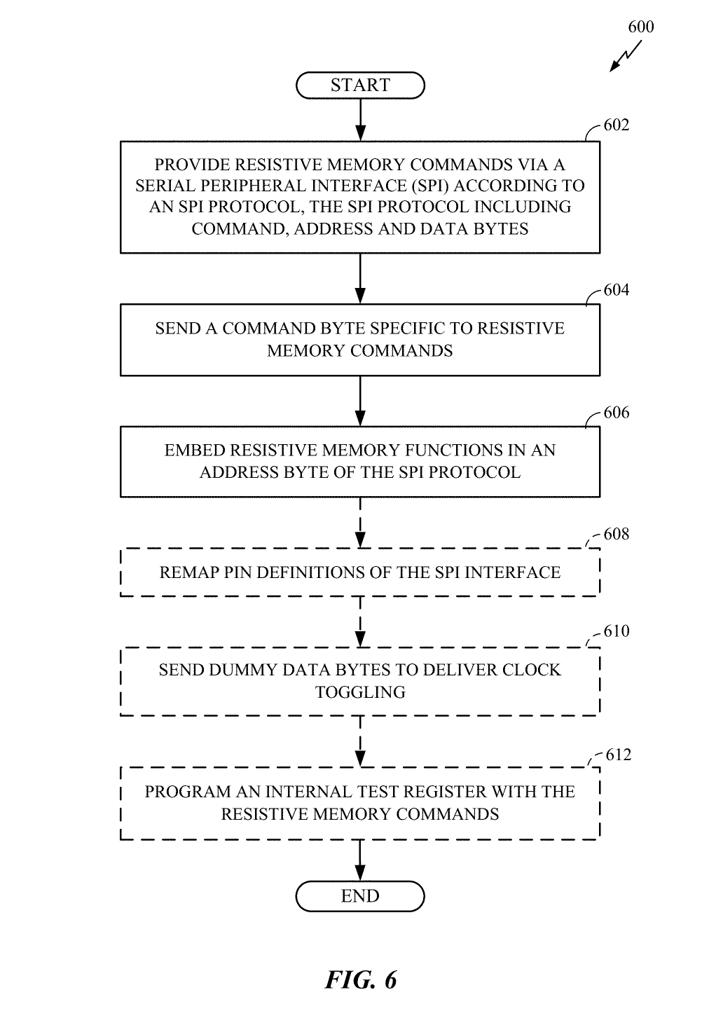

FIG. 6 is a process flow diagram illustrating a method of implementing a serial peripheral interface-magnetic random access memory (SPI-MRAM) according to aspects of the present disclosure. The method 600 includes, at block 602, providing resistive memory commands via a serial peripheral interface (SPI) according to an SPI protocol, the SPI protocol including command, address, and data bytes. For example, the command byte may be 8 bits in length, the address byte may be 24 bits in length, and the data bytes may be of various lengths depending on a desired length of clock toggling or amount of data to be written. These bit values are exemplary only, and other values may be used.

The method may further include, at block 604, sending a command byte specific to resistive memory commands. For example, the command byte may be F8h to indicate an SPI-MRAM protocol operation. Other than the command signal of F8h, which is a new command, the rest of the signals may be based on standard SPI-NOR command sets.

The method may further include, at block 606, embedding resistive memory functions in an address byte of the SPI protocol. For example, the resistive memory functions may include 00h, 01h, 02h, 03h, 04h, etc., to correspond to various functions, such as, including, but not limited to, cold power up, warm power up, built-in self-test (BIST), test register write, and direct access. These signals may be based on standard SPI-NOR command sets.

The method may further include blocks 608, 610, and 612, depending on the desired resistive memory function to be performed. For example, if the resistive memory function remaps pin definitions of the SPI interface (e.g., 02h, 04h, etc.), the method proceeds to block 608. If the resistive memory function uses clock toggling (e.g., 00h, 01h, etc.), the method proceeds to block 610. If the resistive memory function is to write to the internal test register (e.g., 03h, etc.), the method proceeds to block 612. Blocks 608, 610, and 612 may be performed by the SPI-MRAM device, and are described in further detail below.

At block 608, pin definitions of the SPI interface are remapped. For example, for an MRAM built-in self-test resistive memory function (e.g., 02h), the SPI interface is remapped to joint test action group (JTAG) pins for a BIST operation, as follows: the chip select CS# signal pin is remapped to BIST_TCK (e.g., input), the serial data input output 0 SIO0 signal pin is remapped to BIST_TRST_N (e.g., input), the serial data input output 1 SIO1 signal pin is remapped to BIST_TMS (e.g., input), the serial data input output 2 SIO2 signal pin is remapped to BIST_TDI (e.g., input), and the serial data input output 3 SIO3 signal pin is remapped to BIST_TDO (e.g., output).

Alternatively, for an MRAM direct access resistive memory function (e.g., 04h), the SPI interface is remapped to MRAM direct access pins as follows: the chip select CS# signal pin is remapped to MRAM_CS (e.g., input), the serial data input output 0 SIO0 signal pin is remapped to MRAM_WE (e.g., input), the serial data input output 1 SIO1 signal pin is remapped to MRAM_ADDR[0] (e.g., input), the serial data input output 2 SIO2 signal pin is remapped to MRAM_DIN[0] (e.g., input), and the serial data input output 3 SIO3 signal pin is remapped to MRAM_DOUT[0] (e.g., output).

At block 610, dummy data bytes are sent to deliver clock toggling for an MRAM cold power up (e.g., 00h) or an MRAM warm power up (e.g., 01h) resistive memory function. For example, a length of the dummy data bytes may vary in length depending on a desired length of clock toggling. In aspects, 8192 bits are used for a cold power up operation, 2048 bits are used for a warm power up operation, 8 bits are used for a BIST operation, and 8 bits for a direct access operation. These values are exemplary only, and various other values may also be used.

At block 612, an internal test register is programmed with the resistive memory commands for an MRAM test register write resistive memory function (e.g., 03h). For example, the resistive memory commands may be of various bits in length, depending on the length of the resistive memory commands to be written into the internal test register.

According to an aspect of the present disclosure, a system for a resistive memory having a serial peripheral interface (SPI) is described. The system may include controlling means for transmitting resistive memory commands via the SPI according to an SPI protocol. The SPI protocol may include command, address, and data bytes. The transmitting means may be the resistive memory controller 422, as shown in FIG. 4. In another aspect, the aforementioned means may be any module or any apparatus or material configured to perform the functions recited by the aforementioned means.

MRAM is a promising candidate for replacing NAND/NOR flash memory. Adoption of MRAM technology may be improved by adapting the existing serial peripheral interface-NOR (SPI-NOR) protocols with an SPI-MRAM interface for operating, debugging, and monitoring MRAM. Current SPI-NOR uses SPI technology for facilitating communication between a processor and a peripheral device, such as NOR flash memory. For example, a standard SPI-NOR includes both hardware (e.g., signal pins) and software (e.g., command sets) for communicating with a processor as well as other peripheral components. As such, a standard SPI-NOR protocol architecture may provide a framework in which SPI-MRAM may be easily and cheaply integrated to promote wider use.

Aspects of the present disclosure are directed to a system including a resistive memory having a serial peripheral interface (SPI). The system also includes a memory controller operable to provide resistive memory commands via the SPI according to an SPI protocol. The SPI protocol may include command, address, and data bytes. The method may also include sending a command byte specific to resistive memory commands. The method may further include embedding resistive memory functions in an address byte of the SPI protocol. The method may also include remapping pin definitions of the SPI interface. In addition, the method may include sending dummy data bytes to deliver clock toggling.

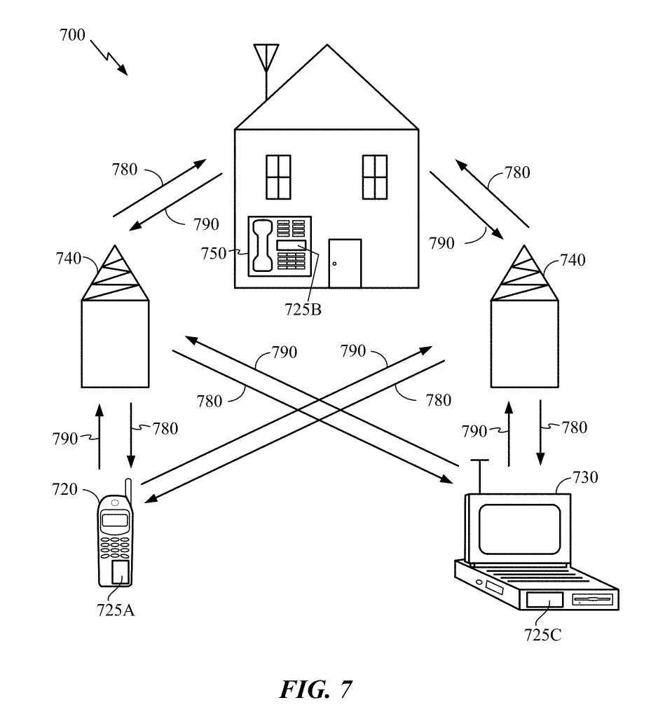

FIG. 7 is a block diagram showing an exemplary wireless communication system 700 in which an aspect of the disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include IC devices 725A, 725C, and 725B that include the disclosed SPI-MRAM devices. It will be recognized that other devices may also include the disclosed SPI-MRAM devices, such as the base stations, switching devices, and network equipment. FIG. 7 shows forward link signals 780 from the base station 740 to the remote units 720, 730, and 750 and reverse link signals 790 from the remote units 720, 730, and 750 to base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communication systems (PCS) unit, a portable data unit such as personal digital assistant (PDA), a GPS enabled device, a navigation device, a set top box, a music player, a video player, an entertainment unit, a fixed location data unit such as a meter reading equipment, or a communications device that stores or retrieves data or computer instructions, or combinations thereof. Although FIG. 7 illustrates remote units according to the aspects of the disclosure, the disclosure is not limited to these exemplary illustrated units. Aspects of the disclosure may be suitably employed in many devices, which include the disclosed SPI-MRAM devices.

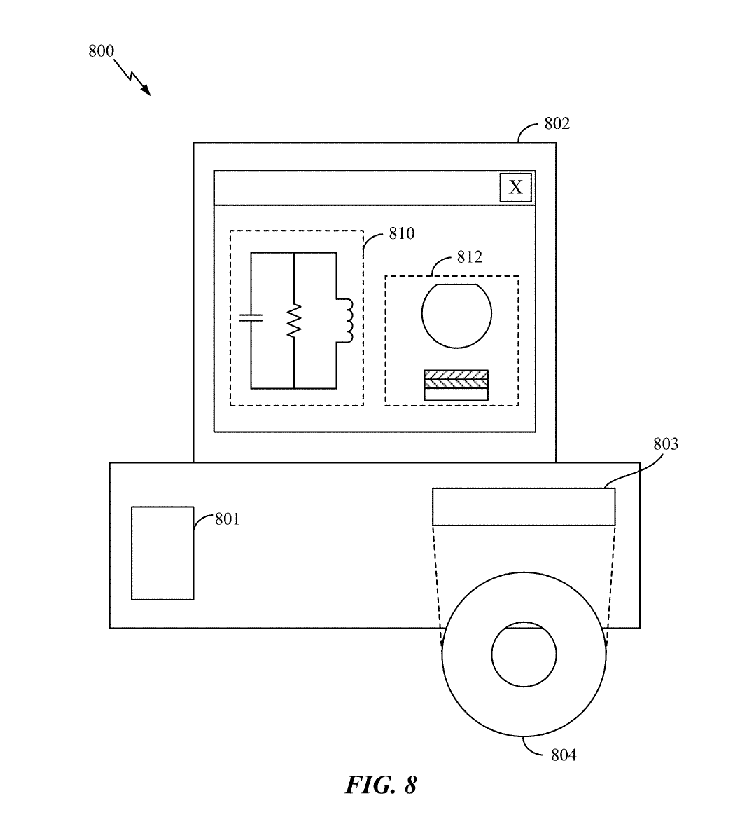

FIG. 8 is a block diagram illustrating a design workstation used for circuit, layout, and logic design of a semiconductor component, such as the SPI-MRAM disclosed above. A design workstation 800 includes a hard disk 801 containing operating system software, support files, and design software such as Cadence or OrCAD. The design workstation 800 also includes a display 802 to facilitate design of a circuit 810 or a resistive memory controller component 812 such as the SPI-MRAM in accordance with an aspect of the present disclosure. A storage medium 804 is provided for tangibly storing the design of the circuit 810 or the semiconductor component 812. The design of the circuit 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the semiconductor component 812 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core), or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “a step for.”

What is claimed is:

1. A method of serial peripheral interface (SPI) communications for a resistive memory, the method comprising:
transmitting resistive memory commands via the SPI to operate the resistive memory according to an SPI protocol, the SPI protocol comprising a command byte, an address byte, and data bytes.

2. The method of claim 1, in which the command byte is specific to the resistive memory commands.

3. The method of claim 1, further comprising embedding resistive memory functions in the address byte of the SPI protocol.

4. The method of claim 1, further comprising remapping pin definitions of an SPI interface for the resistive memory.

5. The method of claim 1, further comprising sending dummy data bytes to perform clock toggling.

6. The method of claim 1, further comprising programming an internal test register with the resistive memory commands.

7. The method of claim 1, further comprising incorporating the resistive memory into at least one of a music player, a video player, an entertainment unit, a navigation device, a communications device, a personal digital assistant (PDA), a fixed location data unit, a mobile phone, and a portable computer.

8. A serial peripheral interface (SPI) resistive memory system, comprising:
a resistive memory having a serial peripheral interface (SPI); and
a memory controller coupled to the resistive memory, the memory controller operable to transmit resistive memory commands via the SPI according to an SPI protocol, the SPI protocol comprising a command byte, an address byte, and data bytes.

9. The system of claim 8, in which the command byte of the SPI protocol comprises a command byte specific to the resistive memory commands.

10. The system of claim 8, in which the address byte of the SPI protocol comprises resistive memory functions.

11. The system of claim 8, in which the data bytes of the SPI protocol comprise dummy data bytes to toggle a clock signal.

12. The system of claim 8, in which the SPI comprises remapped signal pins.

13. The system of claim 8, in which the resistive memory is coupled to the SPI via an SPI bus.

14. The system of claim 8, integrated into at least one of a music player, a video player, an entertainment unit, a navigation device, a communications device, a personal digital assistant (PDA), a fixed location data unit, a mobile phone, and a portable computer.

15. A serial peripheral interface (SPI) resistive memory system, the system comprising:
a resistive memory having a serial peripheral interface (SPI); and
means for transmitting resistive memory commands to the resistive memory via the SPI according to an SPI protocol, the SPI protocol comprising a command byte, an address byte, and data bytes.

16. The system of claim 15, in which the command byte of the SPI protocol comprises a command byte specific to the resistive memory commands.

17. The system of claim 15, in which the address byte of the SPI protocol comprises resistive memory functions.

18. The system of claim 15, in which the SPI for the resistive memory comprises remapped signal pins.

19. The system of claim 15, in which the resistive memory is coupled to the SPI via an SPI bus.

20. The system of claim 15, integrated into at least one of a music player, a video player, an entertainment unit, a navigation device, a communications device, a personal digital assistant (PDA), a fixed location data unit, a mobile phone, and a portable computer.
